(19) United States
(12) Patent Application Publication
(10) Pub. No.: US 2025/0391476 A1
(43) Pub. Date: Dec. 25, 2025

(54) MEMORY CELL, NAND STRING, MEMORY CELL ARRAY, DATA READING METHOD, AND DATA WRITING METHOD

(71) Applicant: BEIJING SUPERSTRING ACADEMY OF MEMORY TECHNOLOGY, Beijing (CN)

(72) Inventors: Zhengyong Zhu, Beijing (CN); Bokmoon Kang, Beijing (CN); Jin Dai, Beijing (CN); Chao Zhao, Beijing (CN)

(73) Assignee: BEIJING SUPERSTRING ACADEMY OF MEMORY TECHNOLOGY, Beijing (CN)

(21) Appl. No.: 18/692,270

(22) PCT Filed: Aug. 10, 2022
(86) PCT No.: PCT/CN2022/111485

§ 371 Date: May 5, 2025

(30) Foreign Application Priority Data
Jul. 7, 2022 (CN) 2022108037136

(51) Int. Cl. G11C 16/10; G11C 16/04; G11C 16/08; G11C 16/26

(52) U.S. Cl. CPC G11C 16/102; G11C 16/0483; G11C 16/08; G11C 16/26

(57) ABSTRACT

A memory cell, an NAND string, a memory cell array, and a data access method. The memory cell comprises a first transistor and a second transistor, the first transistor comprises a first electrode, a second electrode, and two independent gates, i.e., a first gate and a second gate; the second transistor comprises a first electrode, a second electrode, and a gate; the first gate of the first transistor is used as a first word line connecting end; the gate of the second transistor is used as a second word line connecting end; and the second gate of the first transistor is connected to the first electrode of the second transistor.

### CROSS-REFERENCE TO RELATED APPLICATIONS

The present application is a U.S. National Phase Entry of International Application PCT/CN2022/111485 having an international filing date of Aug. 10, 2022, which claims priority of Chinese Patent Application No. 202210803713.6 filed to the CNIPA on Jul. 7, 2022 and entitled “Memory Cell, Nand String, Memory Cell Array, Data Reading Method, and Data Writing Method”, the contents of which are hereby incorporated herein by reference in their entireties.

### TECHNICAL FIELD

Embodiments of the present disclosure relate to, but are not limited to, the field of semiconductor technologies, in particular to a memory cell, an NAND string, a memory cell array, a data reading, and a data writing method.

### BACKGROUND

A basic NAND (i.e. NAND gate) flash block (as shown in FIG. 1) adopts an NAND structure, that is, all memory cells in a column are connected in series without contact, thus saving a lot of area, improving a density of each bit, and thus reducing a cost. When a three-dimensional stacked structure is used, a memory density will be further improved. A basic memory cell of an NAND flash block is a transistor (as shown in FIG. 2), which contains a floating gate or a charge trapping layer. Under a high voltage (about 20V) between a gate and a channel, charges can be injected into or ejected from the floating gate by F-N tunneling or thermal injection. An F-N tunneling current or a thermal current is very low, which leads to that speeds of programming operation and erase operation are relatively low.

### SUMMARY

The following is a summary of subject matter described in detail herein. This summary is not intended to limit the scope of protection of the claims.

Embodiments of the present disclosure provide a memory cell, an NAND string, a memory cell array, a data reading method, and a data writing method.

An embodiment of the present disclosure provides a memory cell, including a first transistor and a second transistor; the first transistor includes a first electrode, a second electrode, and two separated gates: a first gate and a second gate; the second transistor includes a first electrode, a second electrode, and a gate; the first gate of the first transistor serves as a first word line connection end; the gate of the second transistor serves as a second word line connection end; and the second gate of the first transistor is connected to the first electrode of the second transistor.

In an exemplary embodiment, the first electrode of the first transistor is connected to the second electrode of the second transistor.

In an exemplary embodiment, the first electrode of the first transistor is not connected to the second electrode of the second transistor.

In an exemplary embodiment, the second transistor is a transistor having a low off-state current.

An embodiment of the present disclosure provides an NAND string, including a third transistor, multiple memory cells, and a fourth transistor; the multiple memory cells are connected in series through a channel of a first transistor in each memory cell; the third transistor and the fourth transistor are respectively located at two ends of multiple memory cells connected in series; the third transistor and the fourth transistor are connected in series with the multiple memory cells connected in series through respective channels of the third transistor and the fourth transistor; wherein each of the multiple memory cells includes a first transistor and a second transistor; the first transistor includes a first electrode, a second electrode, and two separated gates: a first gate and a second gate; the second transistor includes a first electrode, a second electrode, and a gate; the first gate of the first transistor serves as a first word line connection end; the gate of the second transistor serves as a second word line connection end; and the second gate of the first transistor is connected to the first electrode of the second transistor.

In an exemplary embodiment, the first electrode of the first transistor is connected to the second electrode of the second transistor, and second electrodes of all second transistors in the multiple memory cells connected in series are not connected to each other.

In an exemplary embodiment, the first electrode of the first transistor is not connected to the second electrode of the second transistor, and second electrodes of all second transistors in the multiple memory cells connected in series are connected to each other.

An embodiment of the present disclosure provides a memory cell array, including multiple word lines extending along a first direction, a drain select line extending along the first direction, a source select line extending along the first direction, a source line extending along the first direction, and multiple NAND strings respectively connected to the multiple word lines; wherein the multiple word lines include multiple first word lines and multiple second word lines; a gate of a third transistor of each NAND string is connected to the drain select line; a first bit line is led out from a first electrode of the third transistor of each NAND string; a gate of a fourth transistor of each NAND string is connected to the source select line; a first electrode of the fourth transistor of each NAND string is connected to the source line; a first word line connection end of each memory cell is connected to a corresponding first word line; a second word line connection end of each memory cell is connected to a corresponding second word line; wherein each NAND string includes the third transistor, multiple memory cells, and the fourth transistor; each of the multiple memory cells includes a first transistor and a second transistor; the first transistor includes a first electrode, a second electrode, and two separated gates: a first gate and a second gate; the second transistor includes a first electrode, a second electrode, and a gate; the first gate of the first transistor serves as a first word line connection end; the gate of the second transistor serves as a second word line connection end; and the second gate of the first transistor is connected to the first electrode of the second transistor; the multiple memory cells are connected in series through a channel of the first transistor in each memory cell; the third transistor and the fourth transistor are respectively located at two ends of the multiple memory cells connected in series; the third transistor and the fourth transistor are connected in series with the multiple memory cells connected in series through respective channels; the first electrode of the first transistor is connected to the second electrode of the second transistor, and second electrodes of all second transistors in the multiple memory cells connected in series are not connected to each other.

In an exemplary embodiment, the memory cell arrays are stacked in a third direction to form a three-dimensional stacked structure.

An embodiment of the present disclosure provides a memory cell array, including multiple word lines extending along a first direction, a drain select line extending along the first direction, a source select line extending along the first direction, a source line extending along the first direction, and multiple NAND strings respectively connected to the multiple word lines; wherein the multiple word lines include multiple first word lines and multiple second word lines; a gate of a third transistor of each NAND string is connected to the drain select line; a first bit line is led out from a first electrode of the third transistor of each NAND string; a gate of a fourth transistor of each NAND string is connected to the source select line; a first electrode of the fourth transistor of each NAND string is connected to the source line; a first word line connection end of each memory cell is connected to a corresponding first word line; a second word line connection end of each memory cell is connected to a corresponding second word line; wherein each NAND string includes the third transistor, multiple memory cells, and the fourth transistor; each of the multiple memory cells includes a first transistor and a second transistor; the first transistor includes a first electrode, a second electrode, and two separated gates: a first gate and a second gate; the second transistor includes a first electrode, a second electrode, and a gate; the first gate of the first transistor serves as a first word line connection end; the gate of the second transistor serves as a second word line connection end; and the second gate of the first transistor is connected to the first electrode of the second transistor; the multiple memory cells are connected in series through a channel of the first transistor in each memory cell; the third transistor and the fourth transistor are respectively located at two ends of the multiple memory cells connected in series; the third transistor and the fourth transistor are connected in series with the multiple memory cells connected in series through respective channels; the first electrode of the first transistor is not connected to the second electrode of the second transistor, and second electrodes of all second transistors in the multiple memory cells connected in series are connected to each other.

In an exemplary embodiment, the memory cell arrays are stacked in a third direction to form a three-dimensional stacked structure.

An embodiment of the present disclosure provides a data reading method, applied to the above memory cell array.

The method includes: when reading data in a target memory cell, applying a low voltage to the second word line to turn off all the second transistors; providing a word line in which the memory cell being read is located or a gate of a first transistor of the memory cell being read with a preset voltage; and applying a high voltage to a first word line, the drain select line, and the source select line.

An embodiment of the present disclosure provides a data writing method, including: when writing data to a target memory cell, applying a low voltage to a first word line of which a row number is less than X and the source select line to turn off an associated transistor; applying a high voltage to a first word line of which a row number is greater than or equal to X to make an associated first transistor be in an on state, and applying a low voltage to a second word line other than X to ensure that signals in a bit line are written only to memory cells of X; the row number is a number formed by incrementally numbering, word lines in a direction from a source line to a bit line in a memory cell array, according to the first word line or the second word line respectively; and X is a row in which the target memory cell is located.

An embodiment of the present disclosure provides a data writing method, including: when writing data to a target memory cell, performing a write operation by selecting a second word line and a second bit line corresponding to the target memory cell.

Other aspects may be understood upon reading and understanding the drawings and a detailed description.

### BRIEF DESCRIPTION OF DRAWINGS

FIG. 1 is a schematic diagram of an NAND flash block according to a prior art.

FIG. 2 is a schematic diagram of a memory cell according to a prior art.

FIG. 3 is a schematic diagram of a memory cell according to an embodiment of the present disclosure.

FIG. 4 is a schematic diagram of a memory cell according to an embodiment of the present disclosure.

FIG. 5 is a schematic diagram of another memory cell according to an embodiment of the present disclosure.

FIG. 6 is a schematic diagram of an NAND string according to an embodiment of the present disclosure.

FIG. 7 is a schematic diagram of another NAND string according to an embodiment of

the present disclosure.

FIG. 8 is a schematic diagram of a memory cell array according to an embodiment of the present disclosure.

FIG. 9 is a schematic diagram of another memory cell array according to an embodiment of the present disclosure.

FIG. 10 is a schematic diagram of a transistor output characteristic curve according to an embodiment of the present disclosure.

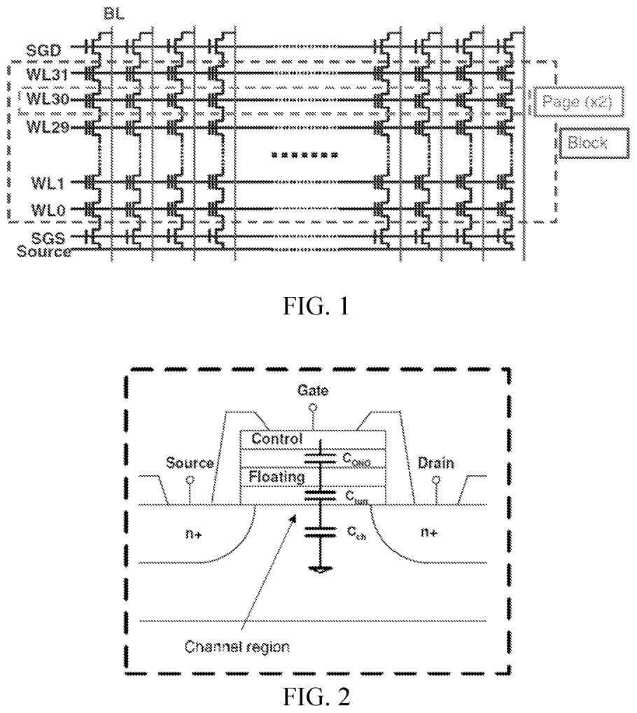

### DETAILED DESCRIPTION

In the embodiments of the present disclosure, in order to distinguish two electrodes of a transistor except a gate thereof, one of the two electrodes is referred to as a first electrode, the other of the two electrodes is referred to as a second electrode, the first electrode may be a source electrode or a drain electrode, the second electrode may be a drain electrode or a source electrode, and in addition, the gate of the transistor is referred to as a control electrode. In a case where transistors with opposite polarities are used or in a case where a direction of a current changes during working of a circuit, etc., functions of the “source” and the “drain” are sometimes interchanged with each other. Therefore, in embodiments of the present disclosure, the “source” and the “drain” may be interchanged with each other.

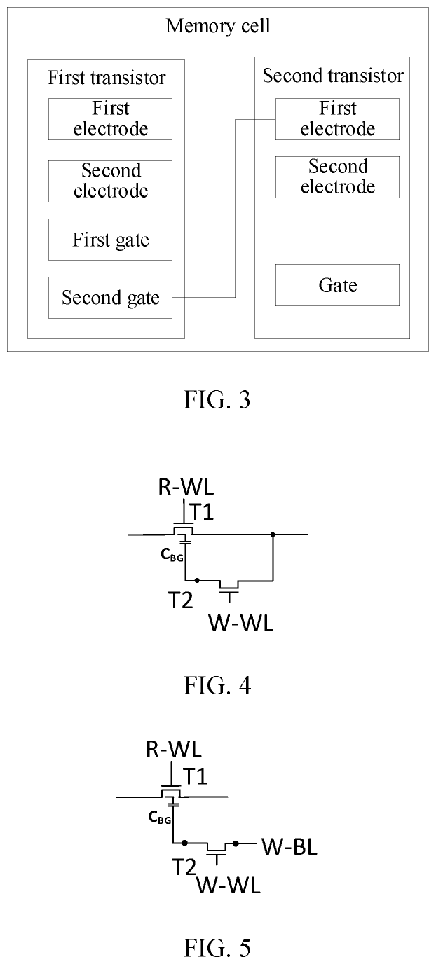

FIG. 3 is a schematic diagram of a memory cell according to an embodiment of the present disclosure. As shown in FIG. 3, the memory cell according to this embodiment may include a first transistor and a second transistor. The first transistor includes a first electrode, a second electrode, and two separated gates, i.e., a first gate and a second gate. The second transistor includes a first electrode, a second electrode, and a gate. The first gate of the first transistor serves as a first word line connection end, the gate of the second transistor serves as a second word line connection end, and the second gate of the first transistor is connected to the first electrode of the second transistor.

In an exemplary embodiment, the first electrode of the first transistor may be connected to the second electrode of the second transistor.

For example, as shown in FIG. 4, the second gate of the first transistor is connected to the first electrode of the first transistor through the second transistor for writing a high voltage or a low voltage to the second gate, and a threshold voltage of the first transistor is changed using a potential (equivalent to charges) of the second gate, so that multi-bit storage with multiple threshold voltages can be achieved.

In an exemplary embodiment, the first electrode of the first transistor may not be connected to the second electrode of the second transistor.

For example, as shown in FIG. 5, the first electrode of the first transistor is not connected to the second electrode of the second transistor.

In an exemplary embodiment, the second transistor is a transistor having a low off-state current. The low off-state current refers to that a current of a transistor is relatively low in a turned-off state.

In an exemplary embodiment, the first transistor or the second transistor may be an NMOS transistor, or may be a PMOS transistor.

The memory cell according to the embodiment of the present disclosure lays a foundation for achieving a high-speed and high-density memory, and an NAND type memory manufactured by using the memory cell have improved writing and refreshing speeds of the memory.

An embodiment of the present disclosure provides an NAND string. The NAND string may include a third transistor, multiple memory cells, and a fourth transistor. The multiple memory cells are connected in series through a channel of a first transistor in each memory cell. The third transistor and the fourth transistor are respectively located at two ends of the multiple memory cells connected in series. The third transistor and the fourth transistor are connected, through their respective channels, in series with the multiple memory cells connected in series. Herein, each of the multiple memory cells includes a first transistor and a second transistor. The first transistor includes a first electrode, a second electrode, and two separated gates, i.e., a first gate and a second gate. The second transistor includes a first electrode, a second electrode, and a gate. The first gate of the first transistor serves as a first word line connection end, the gate of the second transistor serves as a second word line connection end, and the second gate of the first transistor is connected to the first electrode of the second transistor.

In an exemplary embodiment, the first electrode of the first transistor is connected to the second electrode of the second transistor, and second electrodes of all second transistors in the multiple memory cells connected in series are not connected to each other.

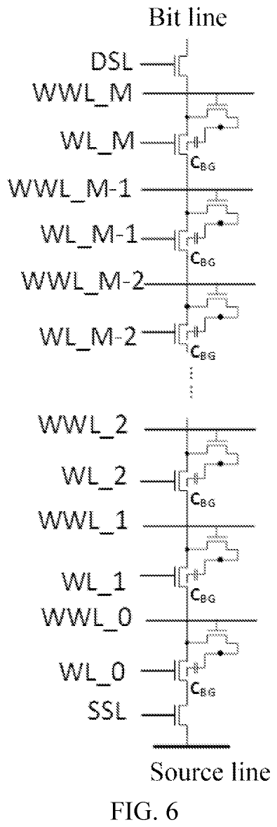

For example, as shown in FIG. 6, the NAND string is configured to complete operations for writing, reading, and refreshing data. The third transistor and the fourth transistor placed at two ends of the NAND string are connected in series with memory cells connected in series through channels. A transistor having a gate as a connection end of a Drain Select Line (DSL) is configured to select a bit line signal, and a transistor having a gate as a connection end of a Source Select line (SSL) is configured to select a control source line.

In an exemplary embodiment, the first electrode of the first transistor and the second electrode of the second transistor are not connected to each other, and second electrodes of all second transistors in the multiple memory cells connected in series are connected to each other.

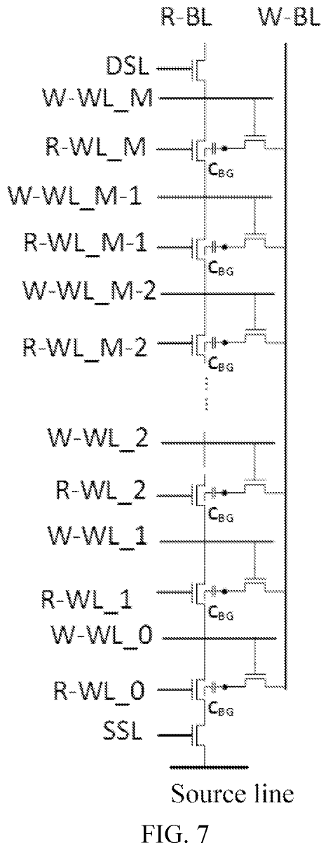

For example, for the NAND string as shown in FIG. 7, second electrodes of second transistors of each memory cell in the string are connected to each other to form a bit line. Although a quantity of bit lines of the string is doubled, since data is written directly to the second gate of the first transistor through the second transistor of the memory cell, a write operation is easier and faster than an existing structure.

An embodiment of the present disclosure provides a memory cell array, which may include multiple word lines extending along a first direction, a drain select line extending along the first direction, a source select line extending along the first direction, a source line extending along the first direction, and multiple NAND strings respectively connected to the multiple word lines. Herein, the multiple word lines include multiple first word lines and multiple second word lines. Each NAND string is the NAND string of the above-described embodiment. A gate of a third transistor of each NAND string is connected to the drain select line. A first bit line is led out from a first electrode of the third transistor of each NAND string. A gate of a fourth transistor of each NAND string is connected to the source select line. A first electrode of the fourth transistor of each NAND string is connected to a source line. A first word line connection end of each memory cell is connected to a corresponding first word line. A second word line connection end of each memory cell is connected to a corresponding second word line. Herein, each NAND string includes a third transistor, multiple memory cells, and a fourth transistor. Each of the multiple memory cells includes a first transistor and a second transistor. The first transistor includes a first electrode, a second electrode, and two separated gates, i.e., a first gate and a second gate. The second transistor includes a first electrode, a second electrode, and a gate. The first gate of the first transistor serves as a first word line connection end. The gate of the second transistor serves as a second word line connection end. The second gate of the first transistor is connected to the first electrode of the second transistor. The multiple memory cells are connected in series through a channel of the first transistor in each memory cell. The third transistor and the fourth transistor are respectively located at two ends of the multiple memory cells connected in series. The third transistor and the fourth transistor are connected, through their respective channels, in series with the multiple memory cells connected in series. The first electrode of the first transistor is connected to the second electrode of the second transistor, and second electrodes of all second transistors in the multiple memory cells connected in series are not connected to each other.

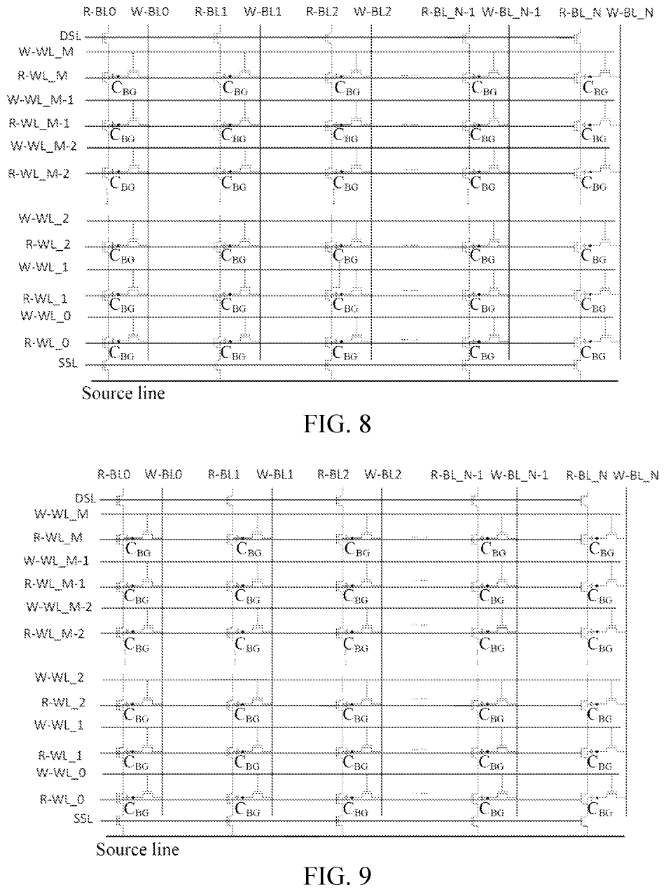

A memory cell array as shown in FIG. 8 may be an example of the memory cell array described above. In FIG. 8, each of BL0 to BL_N is a first bit line, SSL is a source select line, DSL is a drain select line, each of R-WL0 to R-WL_M is a first word line, each of W-WL0 to W-WL_M is a second word line.

In an exemplary embodiment, the memory cell arrays are stacked in a third direction to form a three-dimensional stacked structure to further increase a memory density on chip.

An embodiment of the present disclosure provides a memory cell array, which may include multiple word lines extending along a first direction, a drain select line extending along the first direction, a source select line extending along the first direction, a source line extending along the first direction, and multiple NAND strings respectively connected to the multiple word lines. Herein, the multiple word lines include multiple first word lines and multiple second word lines. A gate of a third transistor of each NAND string is connected to the drain select line. A first bit line is led out from a first electrode of the third transistor of each NAND string. A gate of a fourth transistor of each NAND string is connected to the source select line. A first electrode of the fourth transistor of each NAND string is connected to the source line; a first word line connection end of each memory cell is connected to a corresponding first word line. A second word line connection end of each memory cell is connected to a corresponding second word line. Herein, each NAND string includes a third transistor, multiple memory cells, and a fourth transistor. Each of the multiple memory cells includes a first transistor and a second transistor. The first transistor includes a first electrode, a second electrode, and two separated gates, i.e., a first gate and a second gate. The second transistor includes a first electrode, a second electrode, and a gate. The first gate of the first transistor serves as a first word line connection end. The gate of the second transistor serves as a second word line connection end. The second gate of the first transistor is connected to the first electrode of the second transistor. The multiple memory cells are connected in series through a channel of the first transistor in each memory cell. The third transistor and the fourth transistor are respectively located at two ends of the multiple memory cells connected in series. The third transistor and the fourth transistor are connected in series with the multiple memory cells connected in series through respective channels. The first electrode of the first transistor is not connected to the second electrode of the second transistor, and second electrodes of all second transistors in the multiple memory cells connected in series are connected to each other.

For example, as shown in FIG. 9, each of W-BL0-W-BL_N in FIG. 9 is a second bit line, and each of R-BL0 to R-BL_N is a first bit line. SSL is a source select line, DSL is a drain select line, each of W-WL0 to W-WL_M is a first word line, each of R-WL0 to R-WL M is a second word line, and Source line is a source line.

In an exemplary embodiment, the memory cell arrays may be stacked in a third direction to form a three-dimensional stacked structure to further increase a memory density on chip.

An embodiment of the present disclosure provides a data reading method, which is applied to the above memory cell array.

The method includes: when reading data in a target memory cell, applying a low voltage to the second word lines to turn off all second transistors, providing a word line in which the memory cell being read is located or a gate of the first transistor of the memory cell being read with a preset voltage; and applying a high voltage to the first word lines, the drain select line, and the source select line.

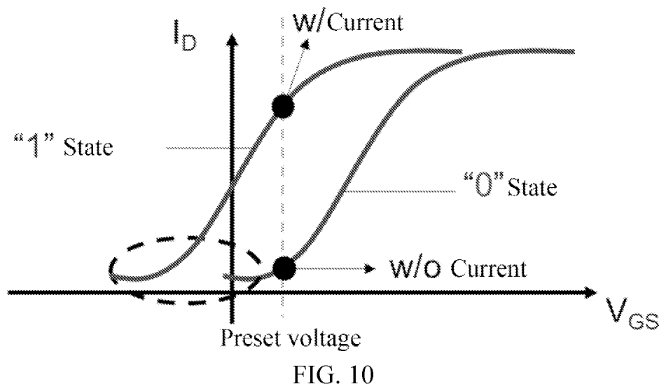

For example, for the memory cell array shown in FIG. 8 or FIG. 9, during a read operation, all W-WLs (i.e., Write Word Lines) are supplied with a low voltage to turn off all second transistors. In order to read a memory cell, its word line or a gate of the first transistor is supplied with a preset voltage (the preset voltage is a voltage that only enables stored data to be read, and an example of the preset voltage is shown in FIG. 10), and it may turn on the first transistor if a high voltage or data “1” is stored in its second gate, but keeps the first transistor turned-off if a low voltage or data “0” is stored. All other WLs (i.e. Word Lines), i.e. gates of other first transistors, as well as SSL and DSL, are provided with a high voltage to ensure that a current (for the data “1”) may flow from a source line to a bit line.

All memory cells in a same row may form a page, so that one page may be read for each time, thus improving a reading speed.

An embodiment of the present disclosure provides a data writing method, including: when writing data to a target memory cell, applying a low voltage to a first word line of which a row number is less than X and a source select line to turn off an associated transistor; applying a high voltage to a first word line of which a row number is greater than or equal to X to make an associated first transistor be in an on state, and applying a low voltage to a second word line other than X to ensure that signals in a bit line are written only to memory cells of X; the row number is a number formed by incrementally numbering, word lines from a source line to a bit line direction in a memory cell array, according to the first word lines or the second word lines respectively; and X is a row in which the target memory cell is located.

For example, for the memory cell array shown in FIG. 8, a write operation is performed from a bottom row to a top row. If memory cells of an X-th row are to be programmed or written, all word lines of which a row number is less than X and the source select line SSL are supplied with a low voltage to turn off all associated transistors, all other WL_Ys (Y≥X) are supplied with a high voltage to make associated T1 transistors be in an on state (i.e., transfer transistors), and W-WL_Y (Y≠X) is supplied with a low voltage to ensure that signals in a bit line are only written to an X-th cell with a word line WWL_X having a high voltage.

An embodiment of the present disclosure provides a data writing method, and the method may include: when writing data to a target memory cell, performing a write operation by selecting a corresponding second word line of the target memory cell and a second bit line.

For example, for the memory cell array shown in FIG. 9, write and read operations are independent and the write operation may be faster, because signals are written to the second gates through only one transistor. By selecting corresponding W-WL and W-BL connected to a target cell, the write operation may be easily implemented.

A refresh operation on data is similar to the write operation.

Multiple embodiments are described in the present disclosure. However, the description is exemplary and unrestrictive. Moreover, it is apparent to those of ordinary skills in the art that there may be more embodiments and implementation solutions within the scope of the embodiments described in the present disclosure. Although many possible combinations of features are shown in the accompanying drawings and discussed in specific implementations, many other combinations of the disclosed features are also possible. Unless expressly limited, any feature or element of any embodiment may be used in combination with, or may replace, any other feature or element in any other embodiment.

Any feature shown or discussed in the present disclosure may be implemented alone or in any suitable combination.

In addition, when a representative embodiment is described, a method or a process may have already been presented in a specific sequence of steps in the specification. However, to an extent of that the method or the process is independent of a specific order of the steps described in this document, the method or the process should not be limited to the steps with the specific order. As will be understood by those of ordinary skills in the art, other orders of steps may also be possible.

It may be understood by those of ordinary skill in the art that all or certain steps in the above disclosed method, systems, and function modules/units in an apparatus may be implemented as software, firmware, hardware, or an appropriate combination thereof. In a hardware implementation, a division of the function modules/units mentioned in the above description is not always corresponding to a division of physical assemblies. For example, a physical assembly may have multiple functions, or a function or a step may be executed by several physical assemblies in cooperation. Some assemblies or all assemblies may be implemented as software executed by a processor such as a digital signal processor or a microprocessor, or implemented as hardware, or implemented as an integrated circuit such as an application specific integrated circuit. Such software may be distributed in a computer-readable medium, and the computer-readable medium may include a computer storage medium (or a non-transitory medium) and a communication medium (or a transitory medium). As known to those of ordinary skills in the art, the term “computer storage medium” includes volatile and nonvolatile, and removable and irremovable media implemented in any method or technology for storing information (for example, computer-readable instructions, a data structure, a program module, or other data). The computer storage medium includes, but is not limited to, RAM, ROM, EEPROM, a flash, or another memory technology, CD-ROM, a Digital Versatile Disk (DVD) or another optical disk storage, a magnetic box, a magnetic tape, a magnetic disk storage or another magnetic storage apparatus, or any other medium that may be configured to store desired information and may be accessed by a computer. In addition, it is known to those of ordinary skills in the art that the communication medium usually includes computer-readable instructions, a data structure, a program module, or other data in a modulated data signal of, such as, a carrier or another transmission mechanism, and may include any information delivery medium.

1. A memory cell, comprising:
a first transistor and a second transistor; the first transistor comprising a first electrode, a second electrode, and two separated gates: a first gate and a second gate; the second transistor comprising a first electrode, a second electrode, and a gate;
wherein the first gate of the first transistor serves as a first word line connection end; the gate of the second transistor serves as a second word line connection end; and the second gate of the first transistor is connected to the first electrode of the second transistor.

2. The memory cell of claim 1, wherein,
the first electrode of the first transistor is connected to the second electrode of the second transistor.

3. The memory cell of claim 1, wherein,
the first electrode of the first transistor is not connected to the second electrode of the second transistor.

4. The memory cell of claim 1, wherein,
the second transistor is a transistor having a low off-state current.

5. An NAND string, comprising:
a third transistor, a plurality of memory cells, and a fourth transistor;
wherein the plurality of memory cells are connected in series through a channel of a first transistor in each memory cell; the third transistor and the fourth transistor are respectively located at two ends of the plurality of memory cells connected in series; the third transistor and the fourth transistor are connected in series with the plurality of memory cells connected in series through respective channels of the third transistor and the fourth transistor;
wherein each of the plurality of memory cells comprises a first transistor and a second transistor; the first transistor comprises a first electrode, a second electrode, and two separated gates: a first gate and a second gate; the second transistor comprises a first electrode, a second electrode, and a gate; and
the first gate of the first transistor serves as a first word line connection end; the gate of the second transistor serves as a second word line connection end; and the second gate of the first transistor is connected to the first electrode of the second transistor.

6. The NAND string of claim 5, wherein,
the first electrode of the first transistor is connected to the second electrode of the second transistor, and second electrodes of all second transistors in the plurality of memory cells connected in series are not connected to each other.

7. The NAND string of claim 5, wherein,
the first electrode of the first transistor is not connected to the second electrode of the second transistor, and second electrodes of all second transistors in the plurality of memory cells connected in series are connected to each other.

8. A memory cell array, comprising:
a plurality of word lines extending along a first direction, a drain select line extending along the first direction, a source line select line extending along the first direction, a source line extending along the first direction, and a plurality of NAND strings respectively connected to the plurality of word lines;
wherein the plurality of word lines comprise a plurality of first word lines and a plurality of second word lines;
each NAND string is the NAND string of claim 6;
a gate of a third transistor of each NAND string is connected to the drain select line; a first bit line is led out from a first electrode of the third transistor of each NAND string; a gate of a fourth transistor of each NAND string is connected to the source select line; a first electrode of the fourth transistor of each NAND string is connected to the source line; a first word line connection end of each memory cell is connected to a corresponding first word line; and a second word line connection end of each memory cell is connected to a corresponding second word line.

9. The memory cell array of claim 8, wherein,
the memory cell arrays are stacked in a third direction to form a three-dimensional stacked structure.

10. A memory cell array, comprising:
a plurality of word lines extending along a first direction, a drain select line extending along the first direction, a source line select line extending along the first direction, a source line extending along the first direction, and a plurality of NAND strings respectively connected to the plurality of word lines;
wherein the plurality of word lines comprise a plurality of first word lines and a plurality of second word lines;
each NAND string is the NAND string of claim 7;
a gate of a third transistor of each NAND string is connected to the drain select line; a first bit line is led out from a first electrode of the third transistor of each NAND string; a second bit line is led out from a second electrode connected in each NAND string; and
a gate of a fourth transistor of each NAND string is connected to the source select line;
a first electrode of the fourth transistor of each NAND string is connected to the source line; a first word line connection end of each memory cell is connected to a corresponding first word line; and a second word line connection end of each memory cell is connected to a corresponding second word line.

11. The memory cell array of claim 10, wherein,
the memory cell arrays are stacked in a third direction to form a three-dimensional stacked structure.

12. A data reading method, applied to the memory cell array of claim 8, wherein the method comprises:
when reading data in a target memory cell, applying a low voltage to the second word lines to turn off all the second transistors; providing a word line in which the memory cell being read is located or a gate of a first transistor of the read memory cell with a preset voltage; and
applying a high voltage to the first word lines, the drain select line, and the source select line.

13. A data writing method, applied to the memory cell array of claim 8, wherein the method comprises:
when writing data to a target memory cell, applying a low voltage to a first word line of which a row number is less than X and the source line select line to turn off an associated transistor; applying a high voltage to a first word line of which a row number is greater than or equal to X to make an associated first transistor be in an on state, and applying a low voltage to a second word line other than X to ensure that signals in a bit line are written only to memory cells of X; the row number is a number formed by incrementally numbering, word lines in a direction from a source line to a bit line in a memory cell array, according to the first word line or the second word line respectively; and X is a row in which the target memory cell is located.

14. A data writing method, applied to the memory cell array of claim 10, wherein the method comprises:
when writing data to a target memory cell, performing a write operation by selecting a second word line and a second bit line corresponding to the target memory cell.

15. The method of claim 12, wherein the memory cell arrays are stacked in a third direction to form a three-dimensional stacked structure.

16. A data reading method, applied to the memory cell array of claim 10, wherein the method comprises:
when reading data in a target memory cell, applying a low voltage to the second word lines to turn off all the second transistors; providing a word line in which the memory cell being read is located or a gate of a first transistor of the memory cell being read with a preset voltage;
and applying a high voltage to the first word lines, the drain select line, and the source select line.

17. The method of claim 16, wherein the memory cell arrays are stacked in a third direction to form a three-dimensional stacked structure.

18. The method of claim 13, wherein the memory cell arrays are stacked in a third direction to form a three-dimensional stacked structure.

19. The method of claim 14, wherein the memory cell arrays are stacked in a third direction to form a three-dimensional stacked structure.
